(19) United States
(12) Patent Application Publication
(10) Pub. No.: US 2017/0228285 A1
(43) Pub. Date: Aug. 10, 2017

(54) DATA DURABILITY IN STORED OBJECTS

(71) Applicant: SwiftStack, Inc., San Francisco, CA (US)

(72) Inventors: Samuel Merritt, Hayward, CA (US); John Dickinson, San Francisco, CA (US); Clay Gerrard, San Francisco, CA (US); Tushar Gohad, Phoenix, AZ (US); Paul Luse, Chandler, AZ (US)

(21) Appl. No.: 15/198,642

(22) Filed: Jun. 30, 2016

Related U.S. Application Data
(60) Provisional application No. 62/293,653, filed on Feb. 10, 2016.

(51) Int. Cl. G06F 11/10; G06F 3/06; H03M 13/15

(52) U.S. Cl. CPC G06F 11/1076; H03M 13/154; G06F 3/0619; G06F 3/064; G06F 3/067

(57) ABSTRACT

Techniques are described for achieving durability of a data object stored in a network storage system. In some embodiments, erasure coding is applied to break a data object into fragments wherein the original data object can be recovered with fewer than all of the fragments. These fragments are stored on multiple storage nodes in a distributed storage cluster of a network storage system. So that individual storage nodes have knowledge of the state of the stored data object, a proxy server acing as a central agent can wait for acknowledgments indicating that the fragments have been successfully stored at the storage nodes. If the proxy server receives successful write responses from a sufficient number of the storage nodes, the proxy server can report that the data object is durably stored by placing markers on the storage nodes.

### CROSS-REFERENCE TO RELATED APPLICATION(S)

This application claims the benefit of U.S. Provisional Patent Application No. 62/293,653, filed on Feb. 10, 2016, entitled “METHOD AND APPARATUS FOR ACHIEVING DATA DURABILITY IN STORED OBJECTS”, which is hereby incorporated by reference in its entirety.

### TECHNICAL FIELD

Various of the disclosed embodiments concern a method and apparatus for achieving durability for stored data objects.

### BACKGROUND

The pervasiveness of the Internet and the advancements in network speed have enabled a wide variety of different applications on storage devices. For example, cloud storage, or more specifically, network distributed data storage system, has become a popular approach for safekeeping data as well as making large amounts of data accessible to a variety of clients. As the use of cloud storage has grown, cloud service providers aim to address problems that are prominent in conventional file storage systems and methods, such as scalability, global accessibility, rapid deployment, user account management, and utilization data collection. In addition, the system's robustness must not be compromised while providing these functionalities.

Among different distributed data storage systems, an object storage system employs a storage architecture that manages data as objects, as opposed to other storage architectures like file systems which manage data as a file hierarchy, and block storage which manages data as blocks within sectors and tracks. Generally, object storage systems allow relatively inexpensive, scalable and self-healing retention of massive amounts of unstructured data. Object storage is used for diverse purposes such as storing photos and songs on the Internet, or files in online collaboration services.

In a distributed storage system, data redundancy techniques can be employed to provide for high availability. One technique includes replication of the data. Replication involves generating one or more full copies of an original data object and storing the copies on different machines in case the original copies gets damaged or lost. While effective at preventing data lost, replication carries a high storage overhead in that each stored object takes up at least 2× more space than it normally would. Another technique include erasure coding (EC) that involves applying mathematical functions to a data object and breaking the data object down into a number of fragments such that the original object can be reconstructed from fewer than all of the generated fragments.

### SUMMARY

Introduced herein are techniques for achieving durability of a data object stored in a network storage system including a proxy server communicatively coupled to one or more storage nodes. In an embodiment, the proxy server receives a request from a client to store a data object in a network storage system. In response to the request the proxy server encodes the data object into fragments, wherein the original object is recoverable from fewer than all of the fragments. The encoding, in some embodiments, can include buffering segments of the data object as they are received from the client and individually encoding each segment using erasure coding into a data fragments and parity fragments. The data fragments and parity fragments are transmitted to the storage nodes where they are concatenated into erasure code fragment archives. Having transmitted the fragments to the storage nodes, the proxy server waits for acknowledgment indicating that the fragments have been successfully stored at the storage nodes. If the proxy server receives a successful write responses from a sufficient number of the storage nodes, the proxy server can report the durable storage of the data object to the client and can place a marker on at least one of the storage nodes indicating that the data object has been durable stored in the network storage system.

### BRIEF DESCRIPTION OF THE DRAWINGS

One or more embodiments of the present disclosure are illustrated by way of example and not limitation in the figures of the accompanying drawings, in which like references indicate similar elements.

FIG. 1 illustrates an example network storage system;

FIG. 2 is a conceptual flow diagram that illustrates an example process for data replication in a network storage system similar to the network storage system of FIG. 1;

FIG. 3 is a conceptual flow diagram that illustrates an example process for durable storage of data using erasure coding in a network storage system similar to the network storage of FIG. 1;

FIGS. 4A-4D are conceptual flow diagrams that illustrates with additional detail an example process for durable storage of data using erasure coding in a network storage system similar to the network storage system of FIG. 1;

FIG. 5 is a conceptual flow diagram that illustrates an example process for reading/retrieving data that has been stored using erasure coding in a network storage system similar to the network storage system of FIG. 1;

FIG. 6 shows an example system of multiple storage nodes in communication with each other in a network storage system similar to the network storage system of FIG. 1; and

FIG. 7 is a block diagram illustrating an example computer processing system in which at least some operations described herein can be implemented.

### DETAILED DESCRIPTION

Various example embodiments will now be described. The following description provides certain specific details for a thorough understanding and enabling description of these examples. One skilled in the relevant technology will understand, however, that some of the disclosed embodiments may be practiced without many of these details.

Likewise, one skilled in the relevant technology will also understand that some of the embodiments may include many other obvious features not described in detail herein. Additionally, some well-known structures or functions may not be shown or described in detail below, to avoid unnecessarily obscuring the relevant descriptions of the various examples.

The terminology used below is to be interpreted in its broadest reasonable manner, even though it is being used in conjunction with a detailed description of certain specific examples of the embodiments. Indeed, certain terms may even be emphasized below; however, any terminology intended to be interpreted in any restricted manner will be overtly and specifically defined as such in this Detailed Description section.

From the foregoing, it will be appreciated that specific embodiments of the invention are described herein for purposes of illustration, but that various modifications may be made without deviating from the scope of the invention. Accordingly, the invention is not limited except as by the appended claims.

### Overview

In distributed object storage systems, Erasure Coding (EC) is a popular method for achieving data durability of stored objects. Erasure Coding is a mechanism where complex mathematics can be applied to a stored data object such that it can be broken down into N fragments, some of which consist of raw data and some of which consist of the results of said mathematical operations, which data is typically referred to as parity or ‘check data.’ Erasure Coding technology also allows for the reconstruction of the original object without requiring the need for all fragments; exactly how many are needed and what the mix of data versus ‘check data’ is depends on the erasure code scheme selected.

Erasure Coding however stops short of defining a means for managing these fragments within the storage system. For a truly shared, nothing distributed, scale out storage system as is typically deployed for Big Data applications in a Software Defined Storage manner, tracking and managing these fragments efficiently and transparently to applications accessing the storage system is a challenging problem, especially when considering that an eventually consistent system, i.e. one that favors availability over consistency, can store a fragment on just about any storage node in the cluster. Without a lightweight means for coordination between nodes to determine when all fragments, on some or all nodes, are stored, an individual storage node may easily wind up with a data fragment that is never deleted and never read. This can happen if a small enough subset of fragments is written to storage nodes, such that the object cannot be reconstructed. In this scenario, the individual storage node has no knowledge of the status of fragments at other nodes, so it cannot easily determine whether a subsequent request for the object should be fulfilled with that particular fragment, or if that particular fragment is part of a partial set that can never be rebuilt.

Described herein are example embodiments that solve these issues by providing mechanisms for placing a marker at a storage node that indicates the state of a stored object and provides the storage node with knowledge of the status of other fragments stored at other nodes. For example, in some embodiments, a proxy server acting as a central agent for a plurality of storage nodes, waits for a sufficient number (quorum) of success responses indicating that a storage node has successfully stored its component of a data object and then places a marker indicating on at least one of the storage nodes indicating that the data object is durably stored across a distributed storage system.

### Example Networked Storage System

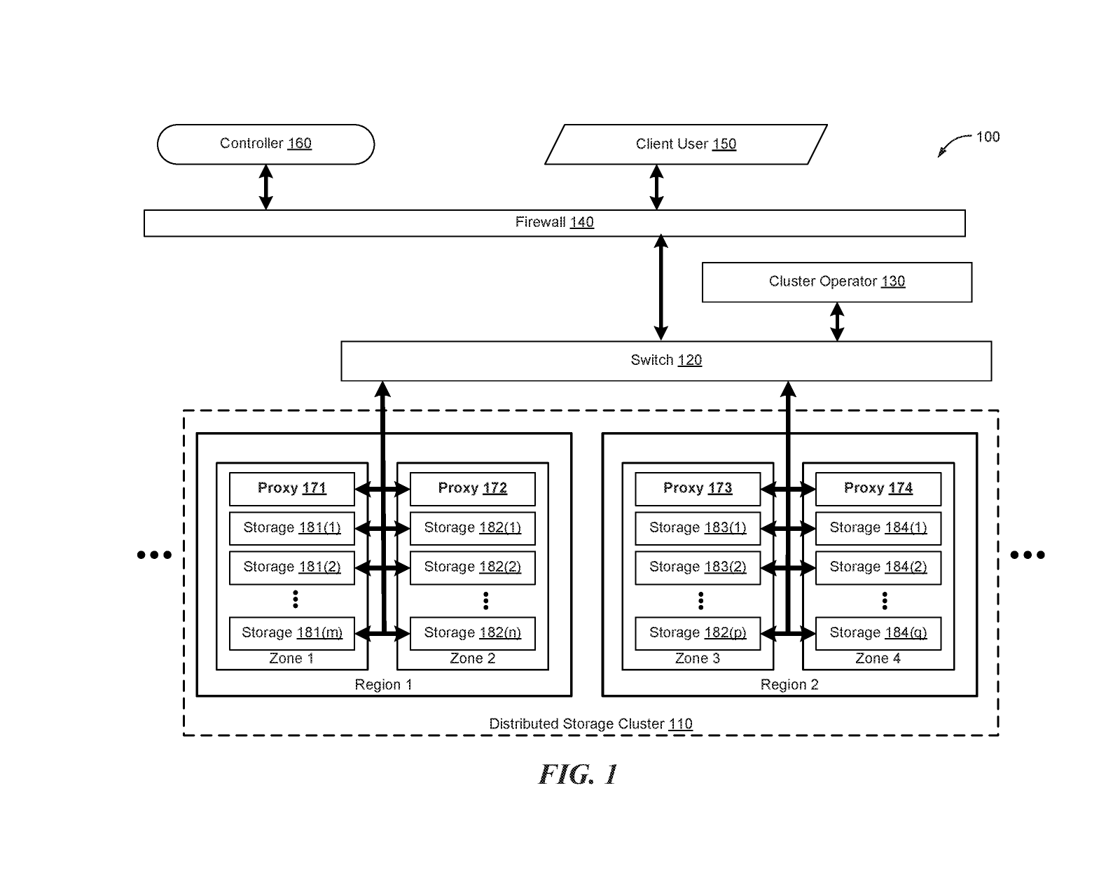

FIG. 1 illustrates an example network storage system 100 in which embodiments of the techniques introduced herein may be utilized. Network storage system 100 can include, for example, distributed storage cluster 110, switch 120, cluster operator 130, firewall 140, client user(s) 150, and a controller 160. One or more of the elements of computing environment 100 can be communicatively coupled to each other through one or more computer communications networks, which can be or include the Internet and one or more wired or wireless networks (e.g., an IP-based LAN, MAN or WAN, a Wireless LAN (WLAN) network, and/or a cellular telecommunications network).

Network storage system 100 can represent an object storage system (e.g., OpenStack Object Storage system, also known as “Swift”), which is a multitenant, highly scalable, and durable object storage system designed to store large amounts of unstructured data. Network storage system 100 is highly scalable because it can be deployed in configurations ranging from a few nodes and a handful of drives to thousands of machines with tens of petabytes of storage. Network storage system 100 can be designed to be horizontally scalable so there is no single point of failure. Storage clusters can scale horizontally simply by adding new servers. If a server or hard drive fails, network storage system 100 automatically replicates its content from other active nodes to new locations in the cluster. Therefore, network storage system 100 can be used by businesses of variable sizes, service providers, and research organizations worldwide. Network storage system 100 can be used to store unstructured data such as documents, web and media content, backups, images, virtual machine snapshots, etc. Data objects can be written to multiple disk drives spread throughout servers in multiple data centers, with system software being responsible for ensuring data replication and integrity across the cluster.

Some characteristics of the network storage system 100 differentiate it from some other storage systems. For instance, in some embodiments, network storage system 100 is not a traditional file system or a raw block device; instead, network storage system 100 enables users to store, retrieve, and delete data objects (with metadata associated with the objects) in logical containers (e.g., via a RESTful HTTP API). Developers can, for example, either write directly to an application programming interface (API) of network storage system 100, can use one of the many client libraries that exist for many popular programming languages (such as Java, Python, Ruby, C#, etc.), among others. Other features of network storage system 100 include being natively designed to store and serve content to many concurrent users, being able to manage storage servers with no additional vendor specific hardware needed, etc. Also, because, in some embodiments, network storage system 100 uses software logic to ensure data replication and durability across different devices, inexpensive commodity hard drives and servers can be used to store the data.

Referring back to FIG. 1, distributed storage cluster 110 can be a distributed storage system used for data object storage. Distributed storage cluster 110 is a collection of machines that run server processes and consistency services (e.g., in the form of “daemons”). A “daemon” is a computer program that can run as a background process or service, in contrast to being under the direct control of an interactive user. Each machine that runs one or more processes and/or services is called a node. When there are multiple nodes running that provide all the processes needed to act as a distributed storage system, such as network storage system 100, the multiple nodes are considered to be a cluster (e.g., distributed storage cluster 110). In some embodiments, there are four server processes: proxy, account, container and object. When a node has only the proxy server process running it is called a proxy node or proxy server, such as proxy servers 171-174. A node running one or more of the other server processes (account, container, or object) is called a storage node, such as storage nodes 181-184. Storage nodes contain data that incoming requests wish to affect (e.g. a PUT request for an object would go to the appropriate nodes running the object server processes). Storage nodes can also have a number of other services running on them to maintain data consistency.

As illustrated in FIG. 1, within a cluster the nodes can belong to multiple logical groups: e.g., regions (such as Region West and Region East, FIG. 1) and zones (such as Zone 1 with proxy server 171 and storage nodes 181(1)-181(m)). Similarly, as shown in FIG. 1, Zone 2 includes proxy server 172 and storage nodes 182(1)-182(n), Zone 3 includes proxy server 173 and storage nodes 183(1)-183(p), and Zone 4 includes proxy server 174 and storage nodes 184(1)-184(q). The arrangement of proxy servers and nodes shown in FIG. 1 is intended to be illustrative and not limiting. Other embodiments may include fewer or more proxy servers and storage nodes than as shown in FIG. 1. Regions and zones are user-defined and identify unique characteristics about a collection of nodes, for example geographic location and points of failure, such as all the power running to one rack of nodes. Having such groups, zones, etc., facilitate efficient placing of data across different parts of the cluster to reduce risk.

The proxy servers 171-174 can function as an interface of network storage system 100, as proxy servers 171-174 can communicate with external clients. As a result, proxy servers 171-174 can be the first and last to handle an API request from, for example, an external client, such as client user 150, which can include any computing device associated with a requesting user. Client user 150 can be one of multiple external client users of network storage system 100. In some embodiments, all requests to and responses from proxy servers 171-174 use standard HTTP verbs (e.g. GET, PUT, DELETE, etc.) and response codes (e.g. indicating successful processing of a client request). Proxy servers 171-174 can use a shared-nothing architecture, among others. A shared-nothing architecture is a distributed computing architecture in which each node is independent and self-sufficient and there is no single point of contention in the system. For example, none of the nodes in a shared-nothing architecture share memory or disk storage. Proxy servers 171-174 can be scaled as needed based on projected workloads. In some embodiments, a minimum of two proxy servers are deployed for redundancy—should one proxy server fail, a second proxy server can take over. However, fewer or more proxy servers than shown in FIG. 1 can be deployed depending on the system requirements.

In general, storage nodes 181-184 are responsible for the storage of data objects on their respective storage devices (e.g. hard disk drives). Storage nodes can respond to forwarded requests from proxy servers 171-174, but otherwise may be configured with minimal processing capability beyond the background processes required to implement such requests. In some embodiments, data objects are stored as binary files on the drive using a path that is made up in part of its associated partition and the timestamp of an operation associated with the object, such as the timestamp of the upload/write/put operation that created the object. A path can be, e.g., the general form of the name of a file/directory/object/etc. The timestamp may allow, for example, the object server to store multiple versions of an object while providing the latest version for a download/get request. In other embodiments, the timestamp may not be necessary to provide the latest copy of object during a download/get. In these embodiments, the system can return the first object returned regardless of timestamp. The object's metadata (standard and/or custom) can be stored in the file's extended attributes (xattrs), and the object's data and metadata can be stored together and copied as a single unit.

Although not illustrated in FIG. 1 for simplicity, a node that runs an account server process can handle requests regarding metadata for individual accounts, or for the list of the containers within each account. This information can be stored by the account server process in SQLite databases on disk, for example. Also, a node that runs a container server process can handle requests regarding container metadata or the list of objects within each container. Note that, in some embodiments, the list of objects does not contain information about the location of the object, and rather may simply contain information that an object belongs to a specific container. Like accounts, the container information can be stored in one or more databases (e.g. an SQLite database). In some embodiments, depending on the deployment, some nodes may run some or all services. Although illustrated as separated in FIG. 1, in some embodiments storage nodes and proxy server nodes may overlap.

In some embodiments, network storage system 100 optionally utilizes a switch 120. In general, switch 120 is used to distribute workload among the proxy servers. In some embodiments, switch 120 is capable of prioritizing TCP and UDP traffic. Further, switch 120 can distribute requests for sessions among a number of resources in distributed storage cluster 110. Switch 120 can be provided as one of the services run by a node or can be provided externally (e.g. via a round-robin DNS, etc.).

Illustrated in FIG. 1 are two regions in distributed storage cluster 110, Region West and Region East. Regions are user-defined and can indicate that parts of a cluster are physically separate. For example, regions can indicate that part of a cluster are in different geographic regions. In some embodiments, a cluster can have one region. Distributed storage cluster 110 can use two or more regions, thereby constituting a multi-region cluster. When a read request is made, a proxy server may favor nearby copies of data as measured by latency. When a write request is made, the proxy layer can transmit (i.e. write) to all the locations simultaneously. In some embodiments, an option called write affinity, when activated, enables the cluster to write all copies locally and then transfer the copies asynchronously to other regions.

In some embodiments, within regions, network storage system 100 allows availability zones to be configured to, for example, isolate failure boundaries. An availability zone can be a distinct set of physical hardware whose failure would be isolated from other zones. In a large deployment example, an availability zone may be configured as a unique facility in a large data center campus. In a single datacenter deployment example, each availability zone may be a different rack. In some embodiments, a cluster has many zones. A globally replicated cluster can be created by deploying storage nodes in geographically different regions (e.g., Asia, Europe, Latin America, America, Australia, or Africa). The proxy servers can be configured to have an affinity to a region and to optimistically write to storage nodes based on the storage nodes' region. In some embodiments, the client can have the option to perform a write or read that goes across regions (i.e., ignoring local affinity).

With the above elements of the network storage system 100 in mind, a scenario illustrating operation of network storage system 100 is introduced as follows. In this example, network storage system 100 is a storage system of a particular user (e.g. an individual user or an organized entity) and client user 150 is a computing device (e.g. a personal computer, mobile device, etc.) of the particular user. When a valid read/retrieve request (e.g. GET) is sent from client user 150, through firewall 140, to distributed storage cluster 110, switch 120 can determine which proxy 171-174 in distributed storage cluster 110 to which to route the request. The selected proxy node (e.g. proxy 171-174) verifies the request and determines, among the storage nodes 181-184, on which storage node(s) the requested object is stored (based on a hash of the object name) and sends the request to the storage node(s). If one or more of the primary storage nodes is unavailable, the proxy can choose an appropriate hand-off node to which to send the request. The node(s) return a response and the proxy in turn returns the first received response (and data if it was requested) to the requester. A proxy server process can look up multiple locations because a storage system, such as network storage system 100, can provide data durability by writing multiple (in some embodiments, a target of 3) complete copies of the data and storing them in distributed storage cluster 110. Similarly, when a valid write request (e.g. PUT) is sent from client user 150, through firewall 140, to distributed storage cluster 110, switch 120 can determine which proxy 171-174 in distributed storage cluster 110 to which to route the request. The selected proxy node (e.g. proxy 171-174) verifies the request and determines, which among the storage nodes 181-184, on which to store the requested data object and sends the request along with the data object to the storage node(s). If one or more of the primary storage nodes is unavailable, the proxy can choose an appropriate hand-off node to which to send the request.

### Data Replication

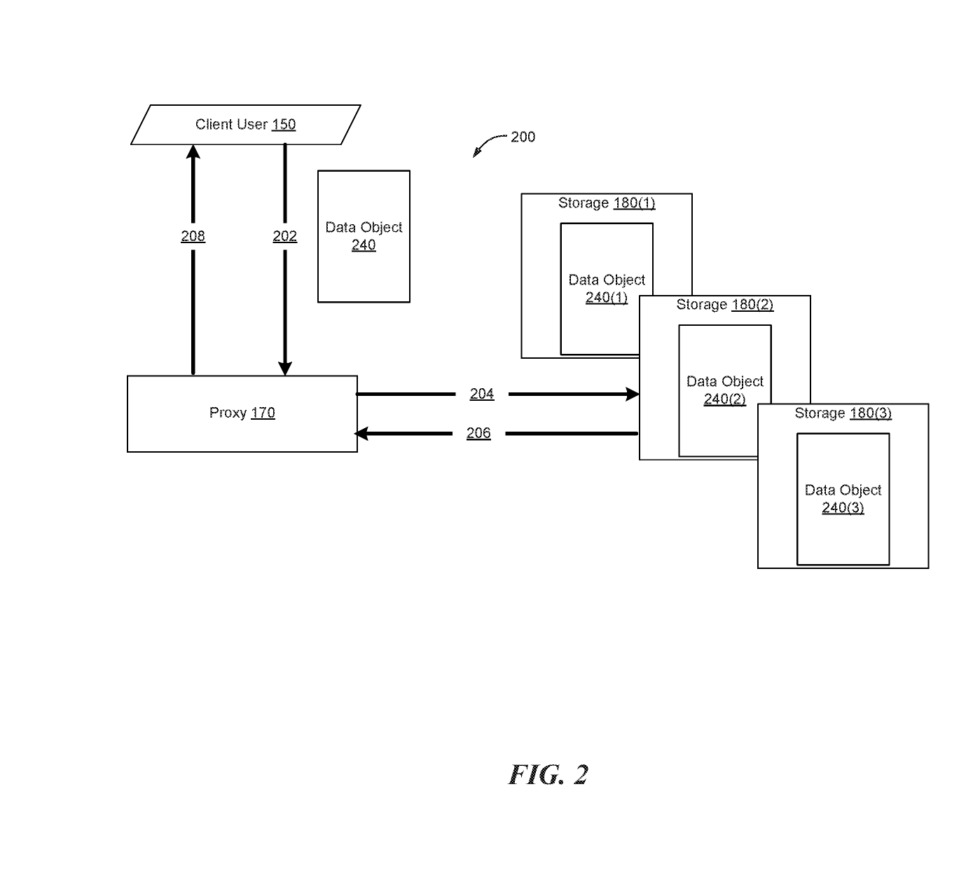

FIG. 2 is a conceptual flow diagram that illustrates an example process 200 for data replication in a network storage system similar to network storage system 100 described with respect to FIG. 1. As shown in FIG. 2, at step 202 a request is received at proxy server 170 (e.g. similar to proxy servers 171-174 in FIG. 1) from client user 150 to store a data object 240 in a distributed storage cluster (e.g. similar to storage cluster 110 in FIG. 1) of a network storage system (e.g. similar network storage system 100 in FIG. 1). As mentioned, in some embodiments this client request is in the form of an HTTP “PUT” statement. In some embodiments, in response to the request from the client 150, proxy server 170 operating as a central agent for the storage nodes in a distributed storage cluster writes the received data object 240 to the storage nodes 180(1), 180(2), and 180(3) at step 204 in three simultaneous PUT statements. In response, at step 206, proxy server 170 receives successful write responses from the storage nodes 180(1), 180(2), and 180(3) if the storage nodes successfully store their respective copy of data object 240. As shown in FIG. 2, the result of this operation is three identical copies 240(1), 240(2), and 240(3) of data object 240 stored on storage nodes 1801(1), 180(2), and 180(3), respectively.

The replication scheme described with respect to FIG. 2 can be described as a triple replication scheme. In such a scheme, if any two of storage nodes 180(1), 180(2), or 180(3) becomes unavailable, the data object 240 is still recoverable as long as one copy remains. In some embodiments, the proxy server 170 can wait for a quorum of success responses from the storage nodes 180(1), 180(2), and 180(3) before reporting at step 208 to the client that the data object 240 is successfully replicated in distributed storage cluster. Here, quorum can be defined as any threshold number of responses, but in a triple replication context quorum can be defined as ⅔ or 2 successful write responses out of 3 simultaneous write requests. This makes sense because in a triple replication scheme, 2 stored copies is the minimum required to be considered replicated. Generally speaking, a quorum can be defined in a replication context as one more than half the number of replicating storage nodes. For example, in a 6× replicating scheme, quorum would be 4 successful write responses.

In a replication scheme, a single write request (e.g. PUT) with a single acknowledgment is all that is required between the proxy and each individual storage node. From the perspective of any of the storage nodes, the operation is complete when it acknowledges the PUT to the proxy as it now has a complete copy of the object and can fulfill subsequent requests without involvement from other storage nodes.

Data replication provides a simple and robust form of redundancy to shield against most failure scenarios. Data replication can also ease scheduling compute tasks on locally stored data blocks by providing multiple replicas of each block to choose from. However, even in a limited triple replication scheme, the cost in storage space is high. Three full copies of each data object are stored across the distributed computing cluster introducing a 200% storage space overhead. As will be described, storing fragments of a data object, for example through the use of erasure coding (EC), can alleviate this strain on storage pace while still maintaining a level of durability in storage.

### Erasure Coding

Erasure Coding (EC) is a mechanism where complex mathematics can be applied to data (e.g. a data object) such that it can is broken down into a number of fragments. Specifically, in some embodiments, an EC codec can operate on units of uniformly sized data cells. The codec takes as an input the data cells and outputs parity cells based on mathematical calculations. Accordingly, the resulting fragments of data after encoding include data fragments which are the raw portions or segments of the original data and “parity fragments” or “check data” which are the results of the mathematical calculations. The resulting parity fragments are what make the raw data fragments resistant to data loss. Erasure Coding technology allows for the reconstruction of the original data object without requiring the need for all fragments; exactly how many are needed and what the mix of data versus ‘check data’ is depends on the erasure code scheme selected. For example, in a standard 4+2 erasure coding scheme, an original data object is encoded into six fragments: four data fragments including portions of the raw data from the original data object, and two parity fragments based on mathematical calculations applied to the raw data. In such a scheme, the original data object is can be reconstructed using any four of the six fragments. For example, the data object can obviously be reconstructed from the four data fragments that include the raw data, but if two of the data fragments are missing, the original data object can be still be reconstructed as long as the two parity fragments are available.

### Durable Storage Using Erasure Coding

Use of erasure coding in a distributed storage context has the benefit of reducing storage overhead (e.g. to 1.2× or 1.5× as opposed to 3×) while maintaining high availability through resistance to storage node failure. However, the process for storing data described with respect to FIG. 2 is limited when applied to erasure coding because a single acknowledgment by a storage node to a write request request provides no information to the storage node as to whether the data object is durably stored across the distributed storage cluster. This is because the durability of the data object depends on the successful write of other fragments of the data object at other storage nodes. Any given storage node is therefore unable to determine how to proceed on subsequent request to retrieve the fragment or during periodic cleanup of outdated fragments.

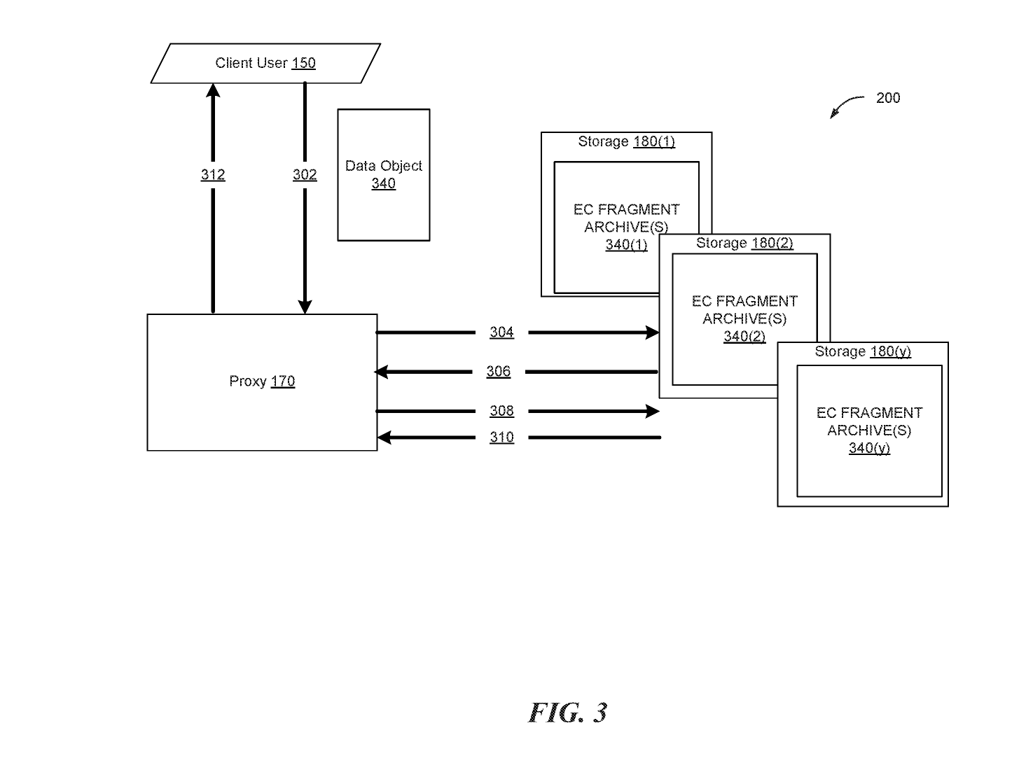

Embodiments described herein solve this problem by introducing an extension to the process involving the initial write request. FIG. 3 is a conceptual flow diagram that illustrates an example process 300 for durable storage of data using erasure coding in a network storage system similar to network storage system 100 described with respect to FIG. 1. As shown in FIG. 3, at step 302 a request is received at proxy server 170 (e.g. similar to proxy servers 171-174 in FIG. 1) from client user 150 to store a data object 340 in a distributed storage cluster (e.g. similar to storage cluster 110 in FIG. 1) of a network storage system (e.g. similar network storage system 100 in FIG. 1). As mentioned, in some embodiments this client request is in the form of an HTTP “PUT” statement. In some embodiments, in response to the request from the client 150, proxy server 170 operating as a central agent for the storage nodes in a distributed storage cluster, encodes the received data object 340 into a plurality of fragments 340(1)-340(y), wherein the data object is recoverable from fewer than all of the plurality of fragments. As previously described encoding the data object may include using erasure coding to generate parity data based on fragments of the underlying raw data of the data object.

Once the data object is encoded into the plurality of fragments (i.e. the data fragments and parity fragments) the proxy server 170 at sept 304 transmits (e.g. through simultaneous PUT statements) the plurality of fragments to one or more of the plurality of storage nodes in a distributed storage cluster. For example in FIG. 3, proxy server 170 transmits the plurality of fragments to a subset y storage nodes 180(1)-180(y). In some embodiments, the transmitted fragments are concatenated with other related fragments into erasure code fragment archives 340(1)-340(y) at the respective storage nodes 180(1)-180(y). To the storage nodes 180(1)-180(y), these EC fragment archives 340(1)-340(y) appear to be data objects.

After transmitting the fragments, the proxy server 170 determines if a specified criterion is satisfied. Specifically, at step 306 proxy server 170 waits to receive a sufficient number of success responses from the storage nodes 180(1)-180(y) indicating that the storage node has successfully stored its fragment of the data object. However, as described earlier, any given storage node 180(1)-180(y) does not know the complete state of storage of the data object across the distributed storage system. Only a central agent (i.e. proxy server 170) having received a sufficient number (i.e. quorum) of acknowledgments from other storage nodes knows if the data object is durably stored. The number of successful responses needed for quorum can be user defined and can vary based on implementation, but generally is based on the erasure code scheme used by for durable storage. In other words, quorum can depend on the number of fragments needed to recover the data object. Specifically, in some embodiments, quorum is calculated based on the minimum number of data and parity fragments required to be able to guarantee a specified fault tolerance, which is the number of data elements supplemented by the minimum number of parity elements required by the chosen erasure coding scheme. For example, in a ReedSoloman EC scheme, the minimum number parity elements required for a particular specified fault tolerance may be 1, and thus quorum is the number of data fragments+1. Again, the number of encoded fragments needed to recover a given data object will depend on the deployed EC scheme.

In response to determining that the specified criterion is satisfied, the proxy server 170 places a marker on at least one of the of storage nodes indicating the state of the data object at the time of writing. For example, if the proxy server 170 receives a quorum of successful write responses from storage nodes 180(1)-180(y), it knows that the data object 340 is durably stored. In other words, even if not all of the transmissions of fragments completed successfully, the data object 340 is still recoverable. Accordingly, to share this knowledge with the storage nodes 180(1)-180(y), the proxy server at step 308 sends a message to and/or places a marker on the storage nodes 180(1)-180(y) indicating a state of the written data object. Preferably a message/marker is sent to all the storage nodes 180(1)-180(y) that have stored fragments of the data object, however in some embodiments only one storage node need receive the message/marker. This message/marker can take the form of a zero byte file using, for example, a time/date stamp and notable extension, e.g. .durable, and can indicate to the storage node that enough of this data object has been successfully stored in the distributed storage cluster to be recoverable. In other words, that the data object is durably stored. With this information, a given storage node can make decisions on whether to purge a stored fragment and how to fulfill subsequent data retrieval requests.

Following the acknowledgement of this second phase at step 310 from a sufficient number (i.e. quorum) of the storage node 180(1)-180(y), the proxy server can at step 312 report successful storage of the data object 340 back to the client user 150.

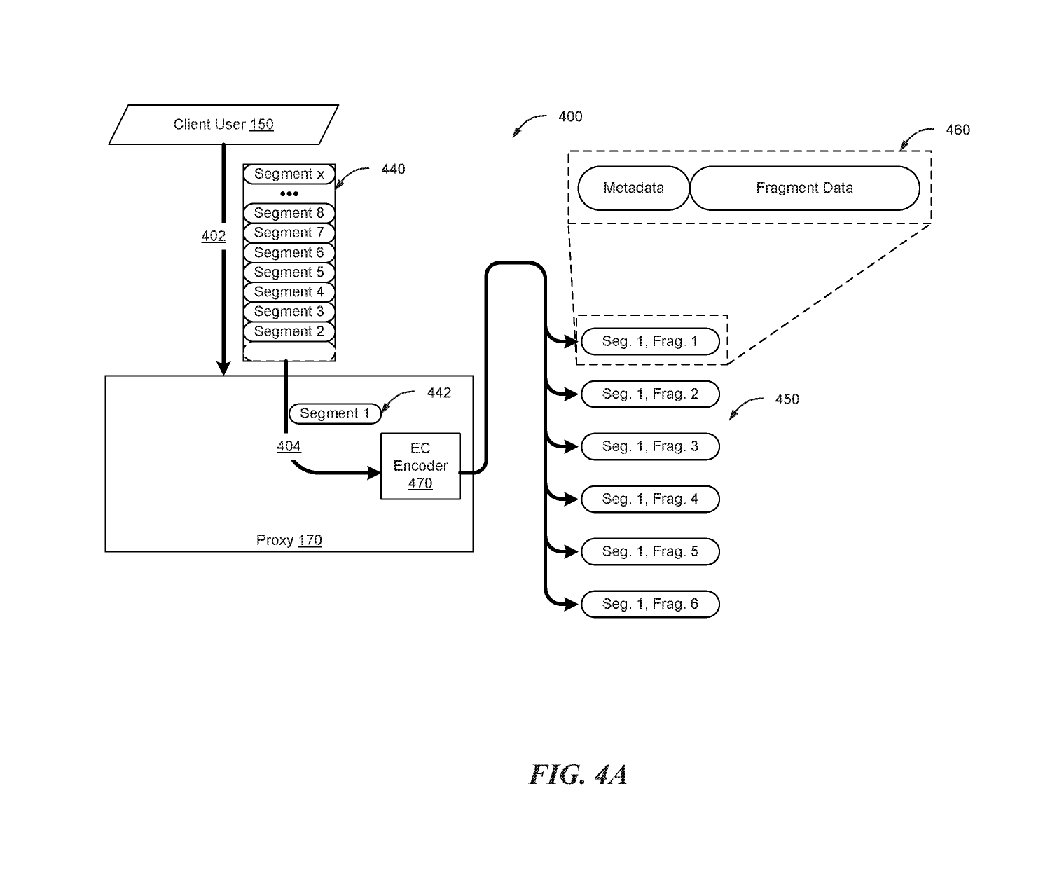

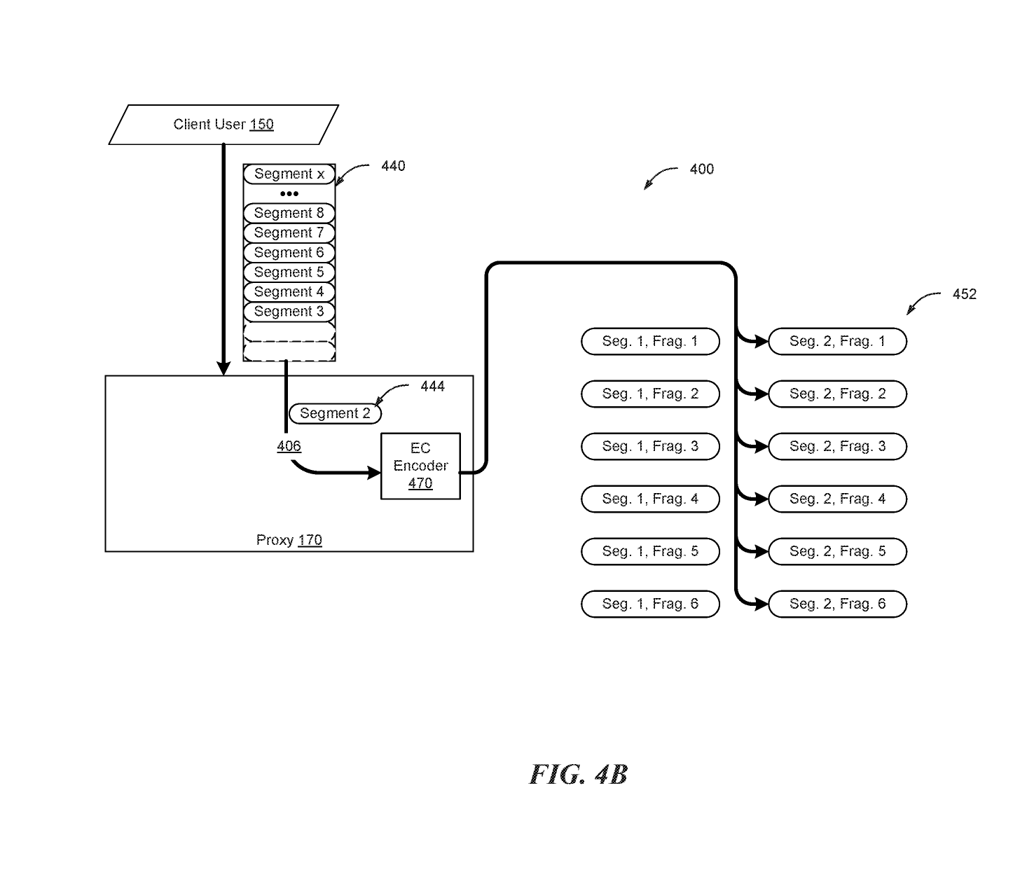

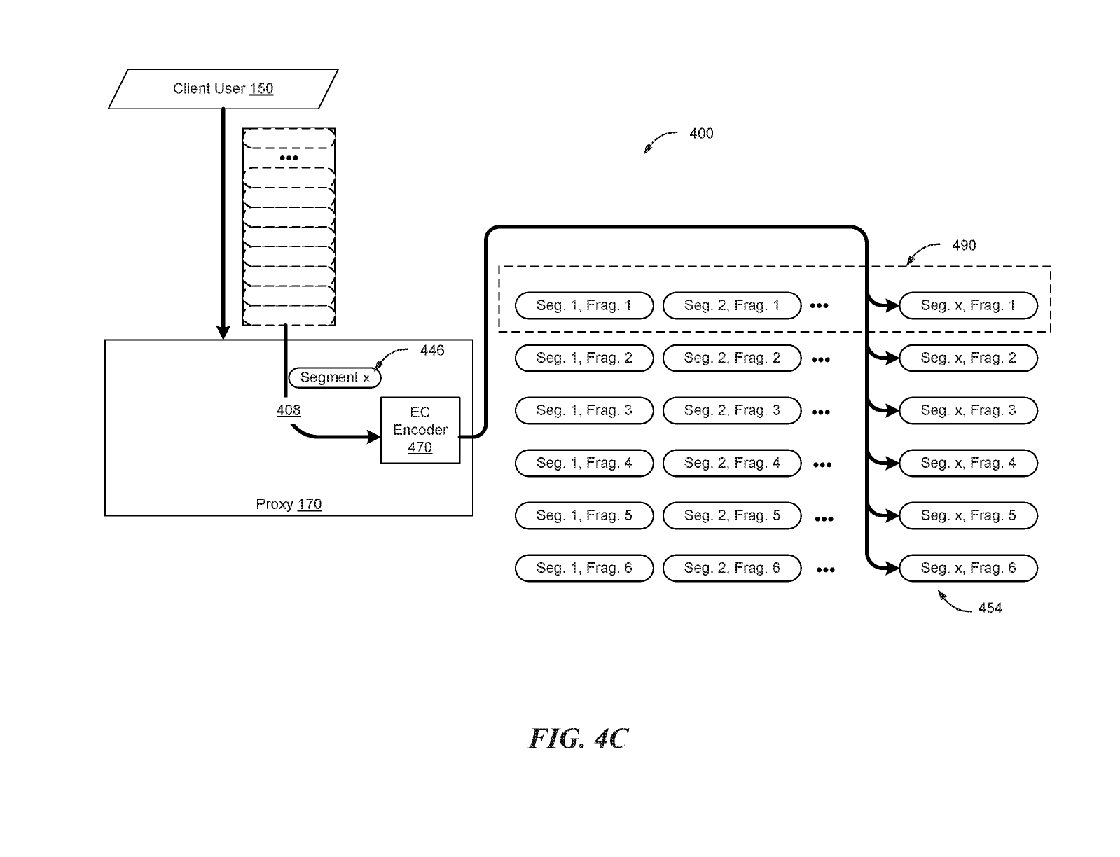

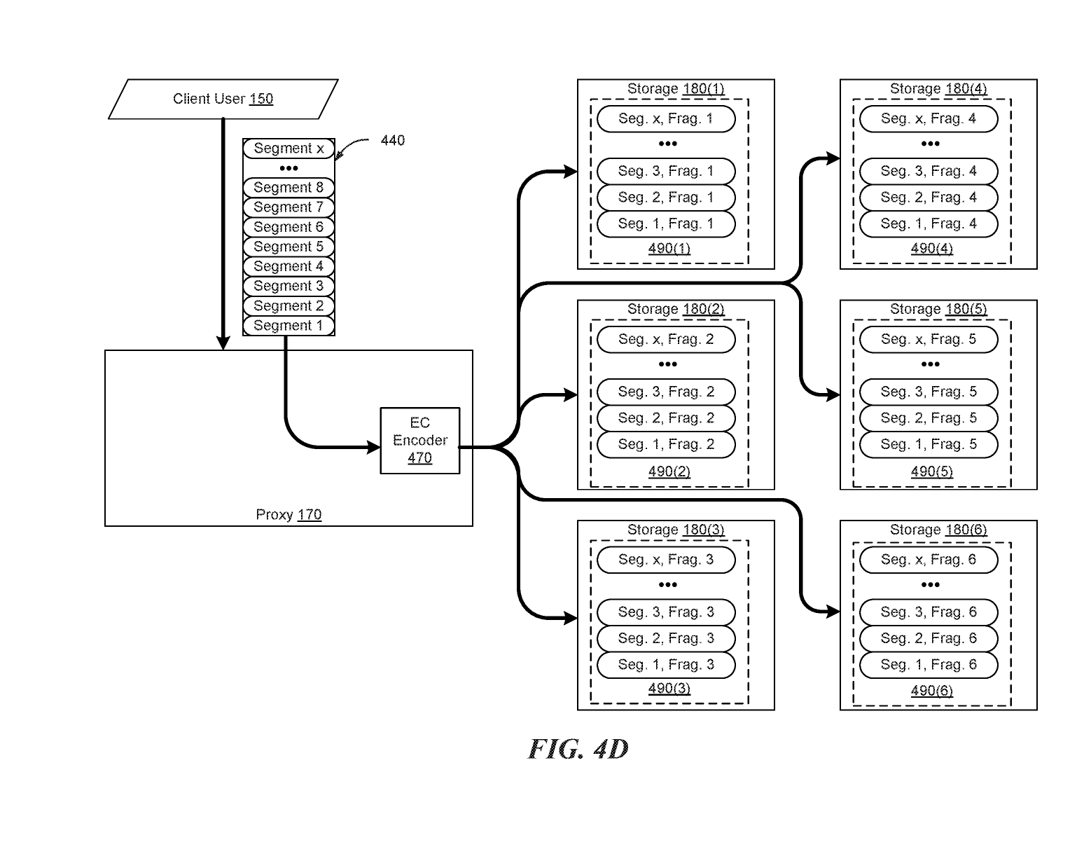

FIGS. 4A-4D are conceptual flow diagrams that illustrates with additional detail example process 400 for durable storage of data using erasure coding in a network storage system similar to network storage system 100 described with respect to FIG. 1.

As shown in FIG. 4A, at step 402 a request is received at proxy server 170 (e.g. similar to proxy servers 171-174 in FIG. 1) from client user 150 to store a data object 440 in a distributed storage cluster (e.g. similar to storage cluster 110 in FIG. 1) of a network storage system (e.g. similar network storage system 100 in FIG. 1). As mentioned, in some embodiments this client request is in the form of an HTTP “PUT” statement. Here, proxy server buffers a first segment 442 of data object 440 for erasure coding. In an HTTP context, a segment is understood as a series of HTTP data chunks buffered before performing an erasure code operation. In some embodiments all of the segments of data object 440 are pre-buffered before performing erasure coding of the segments. In other embodiments, each segment is buffered as it is received from the client user 150 ad is encode as soon as the segment is fully buffered. As shown in FIG. 4A, process 400 involves buffering x segments of data object 440. In other words, data objects can be divided into any number of segments depending on implementation requirement. Segments can have the same or different lengths. In some embodiments, a data object is buffered in 1 MB segments until the entire object is received. In other embodiments, the entire data object is received and divided into x number of equally sized segments.

Having buffered the first segment 442 of data object 440, the proxy server 170 encodes the segment 442 using an EC encoder 470. EC encoder 470 can be a combination of software and/or hardware operating at proxy server 170. As shown in FIG. 4A, EC encoder 470 encodes the segment into a plurality of fragments 450. Specifically, as shown in example process 400, segment 442 is encoded according to a 4+2 EC scheme resulting in six total fragments: four data fragments including the raw data of segment 442, and two parity fragments representing the resulting mathematical calculations performed by EC encoder 470. It shall be understood that EC encoding can result in in more or fewer fragments depending on the EC scheme used. Also shown in FIG. 4A, is a detail 460 of one of the plurality of fragments 450. As shown in detail 460, a fragment (data or parity fragment) can include the fragment data as well as associated metadata providing information about the fragment.

As shown in FIG. 4B, process 400 can continue at step 406 with encoding by EC encoder 470 of a second segment 444 of data object 440. The encoding results in another set 452 of a plurality of fragments. Similarly, as shown in FIG. 4C, process 400 can continue at step 408 with encoding by EC encoder 470 of x segments 446 of data object 440. The encoding results in another set 454 of a plurality of fragments. In some embodiments, a plurality of erasure code fragments can be organized into an erasure code fragment archive 490 as outlined by the dotted line in FIG. 4C. For example, all of the first fragments of each of x segments can be concatenated into erasure code fragment archive 490. In some embodiments, the data and/or parity fragments are concatenated into erasure code fragments archives at proxy server 170 before transmission to one of a plurality of storage nodes. In other embodiments, proxy server 170 transmits fragments to the storage nodes as segments are encoded. In such embodiments, the transmitted fragments are concatenated at their destination storage node into erasure code fragments archives. For example, a particular storage node may first receive segment 1, fragment 1 from proxy server 170 and then append segment 2, fragment 1, once it is received. This process continues until all of the fragments for erasure code fragment archive 490 are received.

FIG. 4D shows the resulting storage of erasure code fragment archives 490(1)-490(6) on storage nodes 180(1)-180(6) following process 400 described with respect to FIGS. 4A-4C assuming that each of the plurality of fragments for each of the plurality of segments is successfully written to the storage nodes. As shown in FIG. 4D, in some embodiments, each erasure code fragment archive includes the fragments from each of the multiple segments of data object 440. For example, erasure code fragment archive 490(1) stored at storage node 180(1) includes the first data fragment (Frag. 1) for each of segments 1 through x. In such an example, Frag. 1 may be a data fragment. Conversely, erasure code fragment archives 490(5) and 490(6) stored at storage node 180(5) and 180(6) may include the fifth (Frag. 5) and sixth (Frag. 6) fragments for each of segments 1 through x. In this example, Frag. 5 and Frag. 6 may be a parity fragments. It shall be understood that the archiving scheme described with respect to FIG. 4D is an illustrative example and is not to be construed as limiting.

Although not shown, in some embodiments fragments of a data object can be replicated for added redundancy across a distributed storage system. For example, in some embodiments upon encoding a particular fragment (e.g. Seg. 1, Frag. 1 shown in FIGS. 4A-4D) proxy server 170 can replicate the particular fragment into one or more replicated (i.e. exact copies) fragments. Proxy server 170 can then transmit the one or more replicated fragments to storage nodes for storage. For redundancy, proxy server 170 can transmit the replicated fragments to different storage nodes than the original fragment. In other words, the replicated fragments are transmitted to a second subset of the multiple of storage nodes. Alternatively, replication of a fragment can be performed at the storage node to which the particular fragment is transmitted. For example, in some embodiments upon receiving and writing a fragment to storage, a storage node can both acknowledge to the proxy server successful write of the fragment, replicate the fragment into multiple replicated fragments and transmit (e.g. through a PUT statement) the multiple replicated fragments to one or more other storage nodes.

After transmitting the replicated fragments, a proxy server and/or storage node can wait for responses indicating successful write of the replicated fragments. Upon receiving responses from a quorum of the storage nodes to which the replicated fragments were transmitted, the proxy server and/or storage node can place a marker on at least one of the storage nodes indicating that the particular fragment is fully replicated.

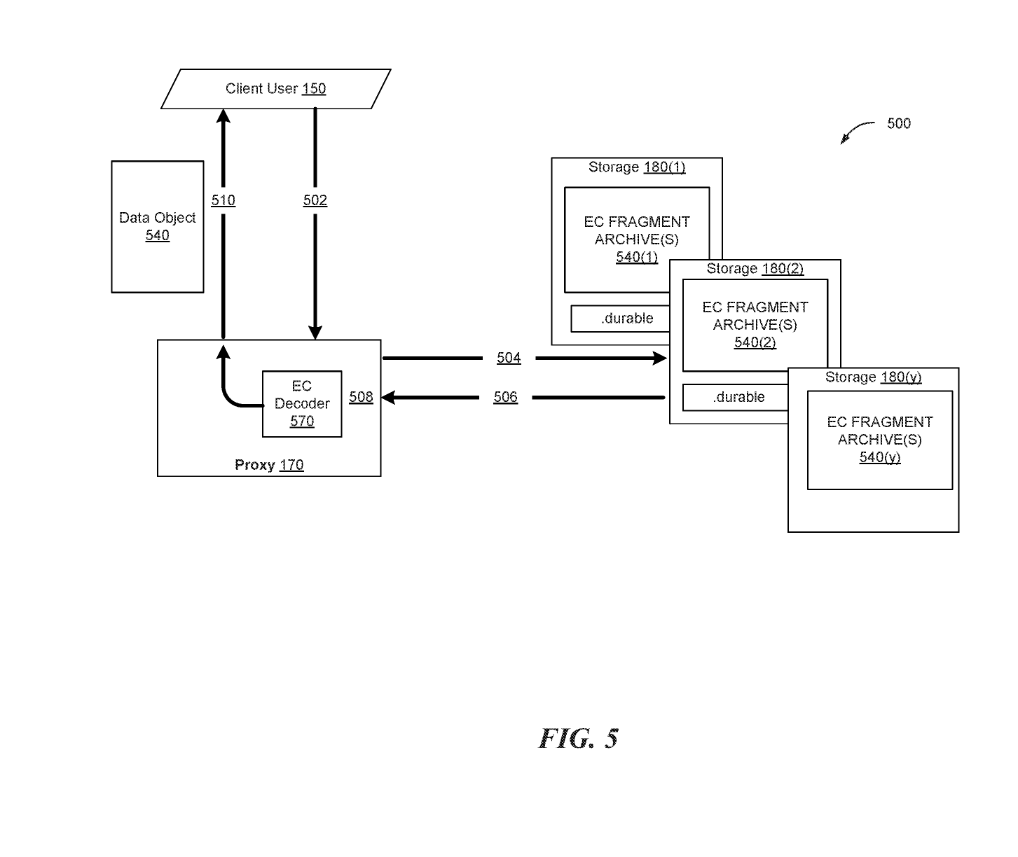

FIG. 5 is a conceptual flow diagram that illustrates an example process 500 for reading/retrieving data that has been stored using erasure coding in a network storage system similar to network storage system 100 described with respect to FIG. 1. As shown in FIG. 5, at step 502 a request is received at proxy server 170 (e.g. similar to proxy servers 171-174 in FIG. 1) from client user 150 to read and/or retrieve a data object 540 stored as multiple fragments 540(1), 540(2) 540(y) in the network storage system. As mentioned, in some embodiments this client request is in the form of an HTTP “GET” statement. The proxy server 170 can then at step 504 open backend connections with the multiple storage nodes 180(1), 180(2), 180(y), validate the number of successful connection and check for the available fragments (e.g. 540(1), 540(2). 540(y)). As discussed with respect to FIG. 4A-4D, in some embodiments, these fragments are erasure code fragment archives. Step 504 may include determining, by proxy server 170, if one or more of the storage nodes storing the fragments include a marker indicating that the data object is durably stored.

In some embodiments, the proxy server 170 can at step 506 conditionally read/retrieve the data object 540 from the storage nodes only if marker is present. Because the data object is stored as a set of fragments (e.g. erasure code fragment archives), proxy server 170 can at step 508 read decode the fragment archives using EC decoder 570 and then at step 510 transmit the now decoded data object 540 to the client 150. As described with respect to FIGS. 4A-4D, the data object may have previously been divided into multiple segments. Accordingly, proxy server can either wait or decode all of the fragments 540(1)-540(y) before assembling the segments into a data object 540 or can transmit segments to the client 150 as they are decoded, where the segments are assembled into the full data object 540 at the client 150.

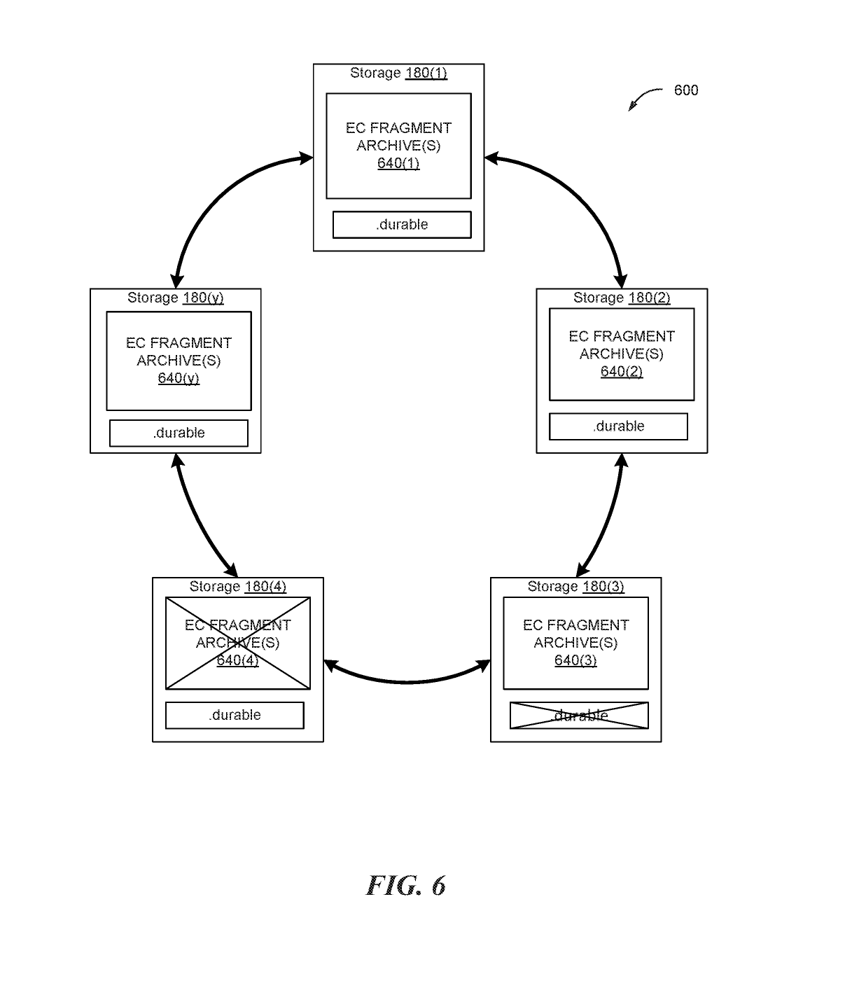

FIG. 6 shows an example system 600 of multiple storage nodes 180(1), 180(2), 180(3), 180(4), and 180(y) in communication with each other, according to some embodiments. Storage nodes 180(1)-180(y) may be part of a distributed storage cluster similar to distributed storage cluster 110 described in FIG. 1. As shown in FIG. 6, system 600 may be set up with a “ring” topology, in which each of the storage nodes 180(1)-180(y) is in communication with the two storage nodes to its left and right in the ring. It shall be understood that this is only an example embodiment and that the storage nodes can be configured to communicate with each other using alternative arrangements.

For illustrative purposes the series of storage nodes 180(1)-180(y) are shown in FIG. 6 with stored EC fragment archives 640(1)-640(y) respectively. As described with respect to FIGS. 4A-4D, these fragment archives may be decoded to retrieve a stored data object (not shown). Further, storage nodes 180(1)-180(y) are shown in FIG. 6 with stored markers indicative of the state of the data object at write. In this example, the markers are zero byte file with a notable extension (e.g. “.durable”). Note that some of the fragment archives (e.g. fragment archive 640(4)) and markers (e.g. at storage node 180(3)) are shown crossed out to indicate that they are unavailable. In this example, unavailable may mean that the data was never received/stored properly, that the data was corrupted or otherwise lost after initial successful storage, or that the data is temporarily unavailable due to hardware/software failure.

As mentioned, in some embodiments, a storage node 180(1)-180*y) can receive from a proxy server (e.g. proxy server 171-174 in FIG. 1) a fragment 640(1)-640(y) of a data object. In response to successfully storing the received fragment, the storage node 180(1)-180(y) can transmit a successful write message to the proxy server. In response to transmitting the successful write message, a storage node 180(1)-180(y) may wait for a period of time for a message/marker from the proxy server indicating that a data object is durably stored in the network storage system.

Consider an example in which storage node 180(3) for whatever reason does not have an available “.durable” marker. In some embodiments, in order to conserver storage space, storage node 180(3) may delete EC fragment archive 640(3) if after a period of time, storage node 180(3) still has not received the marker from the proxy server. Here from the storage node's perspective, because the marker is not present, the data object is not durably stored (i.e. not recoverable) in the network storage system so there is no utility in maintaining the fragment associated with the object in its storage. Alternatively, if storage node 180(3) has not been received the marker from the proxy server within the period of time, storage node 180(3) can communicate with other storage nodes (e.g. nodes 180(2) and 180(4) to determine if the they have received the marker. If storage node 180(3) determines that one or more other storage nodes have received the marker, the storage node can conclude with reasonable certainty that the data object is durably stored despite the absence of the marker in its local storage and can generate its own marker indicating that the data object is durably stored.

Consider another example in which storage node 180(4) for whatever reason does not have fragment archive 640(4) available. Here, storage node 180(4) may have the “.durable” marker available and with the knowledge that the data object is durably stored, communicate with the other storage nodes (e.g. storage nodes 180(y) and 180(3)) to reconstruct fragment archive 180(4). Recall that if the data object is durably stored (i.e. min number of fragments are available) the entire object (including any one of the fragments) is recoverable.

### Additional Applications

The mechanism for placing a marker on a storage device that indicates a state of stored data at write time can be applied to other applications as well. Recall that in some embodiments, in response to determining that a specified criterion is satisfied, a proxy server can place a marker on a storage node that indicates a state of the data (e.g. a data object) at the time of writing. This innovative feature has been described in the context of durable storage using erasure coding, but is not limited to this context.

For example, the aforementioned innovations can be applied in a non-repudiation context to ensure authenticity of stored data. Consider an example of storing a data object in a network storage system. Here the specified criterion may be satisfied if the proxy server receives an indication that authenticates the data object to be stored. For example, the proxy server may wait for review and an authentication certificate from a trusted third party. This trusted third party may be a service provided outside of the network storage system 100 described with respect to FIG. 1. In response to receiving the indication, the proxy server can both report to the client that an authentic copy of the data object is stored and place a marker on at least one of the storage nodes that indicate that an authentic copy of the data object is stored in the network storage system.

As another example, the aforementioned innovations can be applied in a data security context. Again consider an example of storing a data object in a network storage system. Here, the specified criterion may be satisfied if the proxy server receives an indication that the data object is successfully encrypted. For example, in one embodiment, the proxy server may encrypt individual fragments before transmitting to the respective storage nodes. So that the storage nodes have knowledge of the state of the data, the proxy server may additionally transmit a encrypted marker to the storage nodes along with the fragments. Alternatively, encryption may be handled at the storage nodes. Here the proxy server may wait for a quorum of successful encryption responses from the storage nodes before reporting to the client and placing a marker at the storage nodes indicating that the data object is securely stored in the network storage system.

Further, as in the durable storage context, data can be conditionally retrieved/read based on whether the storage nodes include the marker. For example, in a non-repudiation context, the lack of at least one marker may indicate that the data has been tampered with or overwritten by an unauthorized entity since the initial write to storage. Given this conclusion, a storage node and/or proxy server may decline to transmit the existing data object to the client or may at least include a message with the returned data object that the authenticity cannot be verified. Similarly, in a data security context, the lack of at least one marker may indicate that the data was not properly encrypted at the time of write. Again, given this conclusion, a storage node and/or proxy server may decline to transmit the existing data object to the client or may at least include a message with the returned data object that the data was not properly encrypted.

### Example Computer Processing System

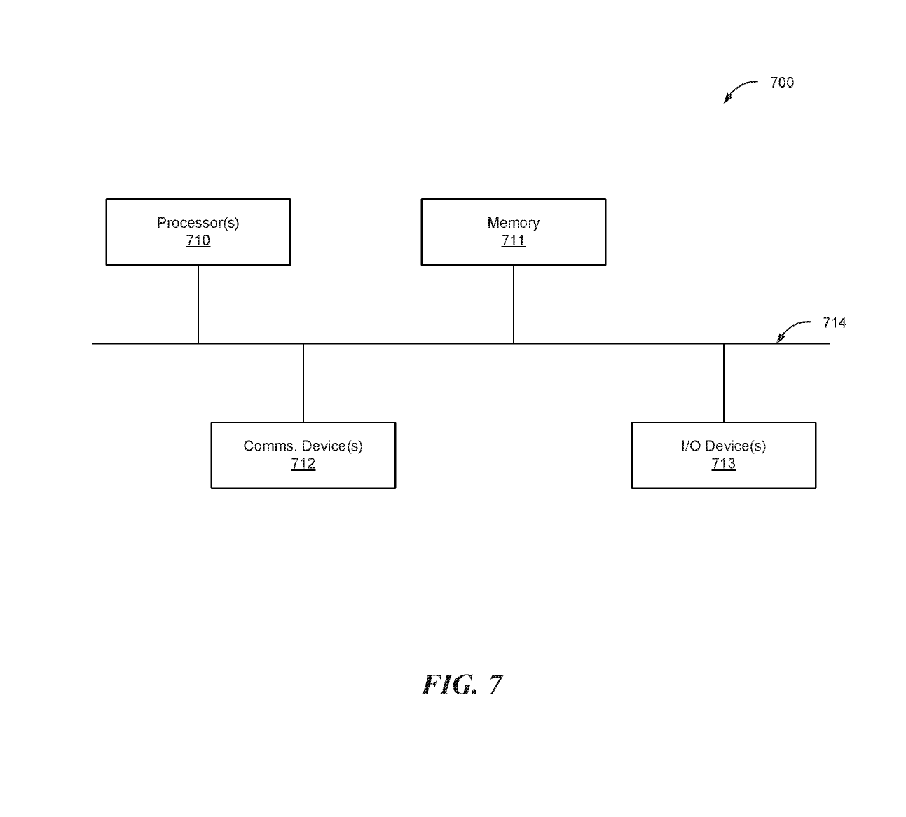

FIG. 7 is a block diagram illustrating an example of a computer processing system 700 in which at least some operations described herein can be implemented, consistent with various embodiments. Computer processing system 700 can represent any of the devices described above, e.g., the controller, the client user, the cluster operator, the switch or the proxy servers and storage nodes of a distributed storage cluster, etc. Any of these systems can include two or more computer processing systems, as is represented in FIG. 7, which can be coupled to each other via a network or multiple networks.

In the illustrated embodiment, the computer processing system 700 includes one or more processors 710, memory 711, one or more communications devices 712, and one or more input/output (I/O) devices 713, all coupled to each other through an interconnect 714. The interconnect 714 may be or include one or more conductive traces, buses, point-to-point connections, controllers, adapters and/or other conventional connection devices. The processor(s) 710 may be or include, for example, one or more central processing units (CPU), graphical processing units (GPU), other general-purpose programmable microprocessors, microcontrollers, application specific integrated circuits (ASICs), programmable gate arrays, or the like, or any combination of such devices. The processor(s) 710 control the overall operation of the computer processing system 700. Memory 711 may be or include one or more physical storage devices, which may be in the form of random access memory (RAM), read-only memory (ROM) (which may be erasable and programmable), flash memory, miniature hard disk drive, or other suitable type of storage device, or any combination of such devices. Memory 711 may be or include one or more discrete memory units or devices. Memory 711 can store data and instructions that configure the processor(s) 710 to execute operations in accordance with the techniques described above. The communication device 712 represents an interface through which computing system X00 can communicate with one or more other computing systems. Communication device 712 may be or include, for example, an Ethernet adapter, cable modem, Wi-Fi adapter, cellular transceiver, Bluetooth transceiver, or the like, or any combination thereof. Depending on the specific nature and purpose of the computer processing system 700, the I/O device(s) 713 can include various devices for input and output of information, e.g., a display (which may be a touch screen display), audio speaker, keyboard, mouse or other pointing device, microphone, camera, etc.

Unless contrary to physical possibility, it is envisioned that (i) the methods/steps described above may be performed in any sequence and/or in any combination, and that (ii) the components of respective embodiments may be combined in any manner.

The techniques introduced above can be implemented by programmable circuitry programmed/configured by software and/or firmware, or entirely by special-purpose circuitry, or by any combination of such forms. Such special-purpose circuitry (if any) can be in the form of, for example, one or more application-specific integrated circuits (ASICs), programmable logic devices (PLDs), field-programmable gate arrays (FPGAs), etc.

Software or firmware to implement the techniques introduced here may be stored on a machine-readable storage medium and may be executed by one or more general-purpose or special-purpose programmable microprocessors. A “machine-readable medium”, as the term is used herein, includes any mechanism that can store information in a form accessible by a machine (a machine may be, for example, any computing device or system including elements similar to as described with respect to computer processing system 700). For example, a machine-accessible medium includes recordable/non-recordable media (e.g., read-only memory (ROM); random access memory (RAM); magnetic disk storage media; optical storage media; flash memory devices; etc.), etc.

### Other Remarks

In this description, references to “an embodiment”, “one embodiment” or the like, mean that the particular feature, function, structure or characteristic being described is included in at least one embodiment of the technique introduced here. Occurrences of such phrases in this specification do not necessarily all refer to the same embodiment. Note that any and all of the embodiments described above can be combined with each other, except to the extent that it may be stated otherwise above or to the extent that any such embodiments might be mutually exclusive in function and/or structure.

Although the disclosed technique has been described with reference to specific exemplary embodiments, it will be recognized that the technique is not limited to the embodiments described, but can be practiced with modification and alteration within scope of the appended claims. Accordingly, the specification and drawings are to be regarded in an illustrative sense rather than a restrictive sense.

What is claimed is:

1. A method comprising:
receiving, by a proxy server, a request from a client to store a data object in a network storage system including a plurality of storage nodes communicatively coupled to the proxy server;
in response to the request from the client, encoding, by the proxy server, the data object into a plurality of fragments, wherein the data object is recoverable from fewer than all of the plurality of fragments;
transmitting, by the proxy server, the plurality of fragments to a subset of the plurality of storage nodes;
in response to determining, by the proxy server, that a specified criterion is satisfied, placing, by the proxy server, a marker on at least one of the subset of storage nodes indicating a state of the written data object.

2. The method of claim 1, wherein the specified criterion is satisfied if the proxy server receives successful write responses from a quorum of the subset of storage nodes within a period of time.

3. The method of claim 2, wherein quorum is based on the number of encoded fragments needed to recover the data object.

4. The method of claim 1, the marker indicates that the data object is durably stored.

5. The method of claim 1, wherein the fragments are stored at the storage nodes as erasure code fragment archives.

6. The method of claim 1, wherein encoding the data object into the plurality fragments includes:
buffering, by the proxy server, a plurality of segments of the data object as they are received from the client: and
for each of the plurality of segments, encoding, by the proxy server, the segment using erasure coding into a plurality of data fragments and parity fragments.

7. The method of claim 6, wherein transmitting the plurality of fragments to the subset of the storage nodes includes transmitting the plurality data fragments and parity fragments to the subset of storage nodes where they are concatenated into a plurality of erasure code fragment archives.

8. The method of claim 1, further comprising:
in response to determining, by the proxy server, that a specified criterion is satisfied, reporting, by the proxy server, the state of the written data object to the client.

9. The method of claim 1, wherein the marker is a zero byte file that includes a time stamp and a notable extension.

10. The method of claim 1, further comprising:
receiving, by the proxy server, a request from the client to read and/or retrieve the data object stored on the network storage system; and
conditionally reading and/or retrieving the data object if at least one of the storage nodes includes the marker.

11. The method of claim 1, wherein at least one of storage nodes includes instructions to delete a stored fragment if it has not received the marker from the proxy server within a specified period of time.

12. The method of claim 1, wherein the specified criterion is satisfied if the proxy server receives an indication that authenticates the data object, and wherein the marker indicates that an authentic copy of the data object is stored in the network storage system.

13. The method of claim 1, wherein the specified criterion is satisfied if the proxy server receives an indication that the fragments are successfully encrypted, and wherein the marker indicates that the data object is securely stored in the network storage system.

14. The method of claim 1, further comprising:
replicating, by the proxy server, a particular fragment of the plurality of fragments into a plurality of replicated fragments; and
transmitting, by the proxy server, the plurality of replicated fragments to a second subset of the plurality of storage nodes; and
in response to receiving, by the proxy server, successful write responses from a quorum of the second subset of the plurality of storage nodes, placing, by the proxy server, a second marker on at least one of the second subset of storage nodes indicating that the particular fragment is fully replicated.

15. A proxy server comprising:
a processing unit;
a network interface coupled to the processing unit; and
a memory unit coupled to the processing unit; the memory unit having instructions stored thereon, which when executed by the processing unit cause the proxy server to:
receive, via the network interface, a request from a client to store a data object in a network storage system including a plurality of storage nodes communicatively coupled to the proxy server;
in response to the request from the client, encode the data object into a plurality of fragments, wherein the data object is recoverable from fewer than all of the plurality of fragments;
transmit, via the network interface, the plurality of fragments to a subset of the plurality of storage nodes; and
in response to determining that a specified criterion is satisfied, place a marker on at least one of the subset of storage nodes indicating a state of the written data object.

16. The proxy server of claim 15, wherein the specified criterion is satisfied if the proxy server receives successful write responses from a quorum of the subset of storage nodes within a period of time, wherein quorum is based on the number of encoded fragments needed to recover the data object, and wherein the marker indicates that the data object is durably stored.

17. The proxy server of claim 15, wherein the instructions to encode the data object into the plurality fragments includes instructions to:
buffer a plurality of segments of the data object as they are received via the network interface from the client; and
for each of the plurality of segments, encode the segment using erasure coding into a plurality of data fragments and parity fragments.

18. The proxy server of claim 17, wherein transmitting the plurality of fragments to the subset of the storage nodes includes transmitting the plurality data fragments and parity fragments to the subset of storage nodes where they are concatenated into a plurality of erasure code fragment archives.

19. The proxy server of claim 15, wherein the memory unit has further instructions stored thereon which when executed by the processing unit cause the proxy server to further:
in response to determining that a specified criterion is satisfied, report the state of the written data object to the client.

20. The proxy server of claim 15, wherein the memory unit has further instructions stored thereon which when executed by the processing unit cause the proxy server to further:
receive, via the network interface, a request from the client to read and/or retrieve the data object stored on the network storage system; and
conditionally read and/or retrieve the data object if at least one of the storage nodes includes the marker.

21. A method comprising:
receiving, by a storage node, a fragment from a proxy server;
in response to successfully storing the received fragment, transmitting, by the storage node, a successful write message to the proxy server; and
in response to transmitting the successful write message, waiting, by the storage node, for a period of time for a marker from the proxy server indicating that a data object is durably stored in the network storage system;
wherein the storage node is one of a plurality of storage nodes communicatively coupled to the proxy server as part of a network storage system;
wherein the fragment is one of a plurality of fragments encoded from the data object; and
wherein the data object is recoverable from fewer than all of the plurality of fragments.

22. The method of claim 21, further comprising:
deleting, by storage node, the received fragment if the marker has not been received from the proxy server within the period of time.

23. The method of claim 21, further comprising:
communicating, by the storage node, with one or more other storage nodes of the plurality of storage nodes if the marker has not been received from the proxy server within the period of time; and
generating, by the storage node, a marker indicating that the data object is durably stored if based on the communicating, the storage node determines that one or more of the other storage nodes received the marker from the proxy server.

24. The method of claim 21, further comprising:
replicating, by the storage node, the fragment into a plurality of replicated fragments; and
transmitting, by the storage node, the plurality of replicated fragments to one or more other storage nodes of the plurality of storage nodes; and
in response to receiving, by the storage node, successful write responses from a quorum of the one or more other storage nodes, placing, by the storage node, a second marker on at least one of the one or more other storage nodes indicating that the fragment is fully replicated.

25. The method of claim 21, wherein the fragment is an erasure code fragment archive including a plurality of data fragments and parity fragments encoded from the data object using erasure coding.
